(19) United States
(12) Patent Application Publication
(10) Pub. No.: US 2004/0036631 A1
(43) Pub. Date: Feb. 26, 2004

(54) Magnetic encoder

(76) Inventor: Toshio Kayao, Okayama (JP)

Correspondence Address: WENDEROTH, LIND & PONACK, L.L.P., 2033 K STREET N. W., SUITE 800, WASHINGTON, DC, 20006-1021, US

(21) Appl. No.: 10/643,886

(22) Filed: Aug. 20, 2003

(30) Foreign Application Priority Data
Aug. 20, 2002 (JP) 2002-238951

(51) Int. Cl. H03M 1/22

(52) U.S. Cl. 341/15

(57) ABSTRACT

A magnetic encoder (6) which is used in a wheel bearing, that forms a pulse train by means of a magnetic force, and generates a code, comprising a magnetic ring (1), a reinforcing ring (2), and a protecting cover (3). The magnetic ring (1) is fixed to said reinforcing ring (2) and circumferentially magnetized with alternate S poles and N poles. The protecting cover (3) is made of a non-magnetic material and wraps around the magnetic ring (1). A plural number of weld-adhering parts are provided between an end part and/or end parts on a radial inner circumferential side and/or a radial outer circumferential side of the protecting cover (3), and the reinforcing ring (2).

### BACKGROUND OF THE INVENTION

1. Field of the Invention

The present invention relates to a magnetic encoder having a tough integrated structure, which is strong against impact as well as predominant in the productivity and the cost.

2. Description of the Related Art

Previously, as a magnetic encoder, taking damage due to foreign material biting and shape distortion into consideration, a magnetic encoder composed of a rubber material having the magnetism and the abundant elasticity has been used mainly.

Such magnetic encoder is generally formed by mixing a magnetic powder into a rubber material and placing it with a reinforcing ring into a mold, followed by heating, pressing, vulcanizing and adhering. Thereby, the vulcanized rubber ring is fixed on the reinforcing ring. And then, the vulcanized rubber ring is magnetized circumferentially with alternate S poles and N poles.

Here, as a magnetic powder, a magnetic powder of ferrite has been generally adopted. Since a magnetic material composed of a rare earth is inferior in the kneading workability and the moldability, and has the high cost, it has been said that the magnetic material composed of a rare earth is not suitable for mixing into a rubber material, and it has not been generally adopted. However, paying an attention to a magnitude of the magnetic force of magnetic material composed of a rare earth, adaptation of it has recently been studied.

Although a magnetic encoder formed of a rubber material is excellent in the moldability, it can not stand strong against impact and, during it is used and worked or during an attaching process of it, a magnetic encoder formed of a rubber material is damaged in some cases.

So that, a structure in which the surface of a magnetic encoder is covered with a rigid protecting cover has been developed, and put into practice.

In a structure in which a magnetic encoder is covered with a rigid protecting cover, it becomes necessary to attach and integrate a protecting cover to a reinforcing ring constituting a magnetic encoder. For this reason, a manufacturing process is increased, and work is laborious. In addition, for this reason, the cost for manufacturing products is increased.

The aforementioned attachment and integration have generally been performed as follows.

One way is to make, in advance, a protecting cover into a form wrapping around a magnetized magnetic ring, and adhere and fix the protecting cover to a reinforcing ring via an adhesive.

Another way is to make, in advance, a protecting cover into a form wrapping around a magnetized magnetic ring and, at the same time, extend an edge part of the protecting cover. This extended edge part is deformed, caulked and engaged so as to fix the protecting cover to a reinforcing ring.

However, these conventional attaching and integrating methods have the following problems.

When adhering and fixing is performed using an adhesive, in some cases, an adhering force is reduced with time due to denaturation of an adhesive.

In addition, when caulking and engaging are performed to fix a protecting cover to a reinforcing ring, there is a problem on a precision of tight attachment to a magnetic encoder. When the aforementioned extended edge part is excessively deformed in order to attain firm fixing, there is a possibility that a magnetized magnetic ring, which is wrapped by the protecting cover, is deformed and damaged. Conversely, when an edge part of a protecting cover is mildly deformed, stable integration and strong integrated structure can not be obtained.

Further, when caulking and engaging are performed to fix a protecting cover to a reinforcing ring, since a part of a protecting cover, for example, an edge part of protecting cover is enforced to be deformed, there arises easily an influence on other parts in a working process of deformation. For example, even a magnetic pole surface of a magnetized magnetic ring is distorted. When a magnetic pole surface is distorted, a gap degree between a sensor which is disposed opposite to a magnetic encoder is deteriorated, and there arises a disorder that a measuring precision is reduced.

### SUMMARY OF THE INVENTION

In view of the aforementioned problems of the conventional magnetic encoder, an object of the present invention is to provide a magnetic encoder having a tough integrated structure, and which is strong against impact as well as predominant in the productivity and the cost.

A magnetic encoder of the present invention is used in a wheel bearing. This magnetic encoder of the present invention forms a pulse train by means of a magnetic force, and generates a code, and comprising a magnetic ring, a reinforcing ring, and a protecting cover.

Wherein, said magnetic ring is fixed to said reinforcing ring and circumferentially magnetized with alternate S poles and N poles.

And, said protecting cover is made of a non-magnetic material and wraps around said magnetic ring.

Further, in the before described magnetic encoder of the present invention, it is characterized that a plural number of weld-adhering parts are provided between an end part and/or end parts on a radial inner circumferential side and/or a radial outer circumferential side of said protecting cover, and said reinforcing ring.

In the above description, a magnetic ring can be prepared by forming a ring-like shaped single magnet using a magnetic material such as ferrite or rare earth, and circumferentially magnetizing the said ring-like shaped single magnet with alternate S poles and N poles.

Alternatively, a bond magnet, a cast magnet and a sintered magnet may be used as the above described magnetic ring, in which a magnetic powder is mixed into a rubber material or a plastic material to form a ring, and circumferentially magnetizing it with alternate S poles and N poles. In this case, as a magnetic powder, magnetic materials such as ferrite, rare earth, MK steel, Alnico and the like can be used.

In the magnetic encoder of the present invention, a plural number of weld-adhering parts are provided between an end part and/or end parts on a radial inner circumferential side and/or a radial outer circumferential side of a protecting cover, and a reinforcing ring. That is, there are weld-adhered parts, which are weld-adhered to a reinforcing ring, at an end part and/or end parts on a radial inner circumferential side and/or radial outer circumferential side of a protecting cover.

So that, it is not necessary to apply forced deformation in order to attach or integrate a protecting cover to a reinforcing ring, thereby attachment and integration process can be proceeded easily. In addition, after attachment or integration, a distortion does not remain on a magnetic pole surface of a magnetized magnetic ring. Therefore, a gap degree between a magnetic encoder and a sensor, which is disposed opposite to a magnetic encoder, can be retained constant, and a high measurement precision can be exerted.

Further, by adopting weld-adhesion as a fixing method, more stable and firm adhesion, and integration with a rein forcing ring have become possible as compared with adhesion using an adhesive, caulking, and fixing by engagement which have conventionally been performed. In addition, an attachment precision has become higher. Further, execution itself has become easy as compared with a fixing method such as caulking.

In the aforementioned magnetic encoder of the present invention, at an end part and/or end parts on a radial inner circumferential side and/or radial outer circumferential side of a protecting cover, a part which is weld-adhered to a reinforcing ring may be over an entire circumference of a protecting cover.

Alternatively, in the aforementioned magnetic encoder of the present invention, at an end part and/or end parts on a radial inner circumferential side and/or radial outer circumferential side of a protecting cover, weld-adhesion may be performed at plural places of 3 to 6 places at a predetermined interval. When weld-adhered at plural places of 3 to 6 places, sufficient strength and firm integration can be obtained.

In the aforementioned magnetic encoder of the present invention, the aforementioned weld-adhering part is desirably formed by weld-adhering an end part and/or end parts on a radial inner circumferential side and/or a radial outer circumferential side of a protecting cover to a reinforcing ring by micro-spot welding using the laser light. The reason is that, by using micro-spot welding using the laser light, distortion and thermal influence on parts other than a welded part can be minimized.

In order to minimize distortion and thermal influence on parts other than a welded part, for example, weld-adhesion to a reinforcing ring may be performed using YAG laser. YAG laser refers to a laser using yttrium-aluminium-garnet crystal containing Nd.

According to the present invention, there can be provided a magnetic encoder which is hardly damaged not only when a magnetic ring having a single magnet as a magnetic material is used, but also when a magnetic ring composed of a rubber material, which is weak to impact and may be damaged during it is used and worked or during an attaching process, is used.

In addition, in the magnetic encoder of the present invention, since a protecting cover is directly weld-adhered to a reinforcing ring, which reinforces a magnetic ring, integrity between a reinforcing ring and a protecting cover can be enhanced, and a tough integrated structure can be obtained.

In addition, by weld-adhesion, a high attachment precision can be realized. Since attachment of a protecting cover at a high precision leads to enhancement of a sensing precision of a magnetic sensor, a measurement precision of a magnetic encoder can be dramatically enhanced.

Further, by weld-adhesion, a manufacturing process becomes easy, and the productivity can be enhanced.

Due to these various effects, the lower cost of a high performance magnetic encoder can be realized.

### BRIEF DESCRIPTION OF THE DRAWINGS

FIG. 1 is a partial cross-sectional view of an example in which weld-adhesion between a reinforcing ring and a protecting cover is performed on a radial inner circumferential side of a magnetic encoder;

FIG. 2 is a partially exploded perspective view explaining the state where a magnetic ring is attached to a reinforcing ring;

FIG. 3 is a partial cross-sectional view of an example in which weld-adhesion between a reinforcing ring and a protecting cover is performed on a radial outer circumferential side of a magnetic encoder; and

FIG. 4 is a partial cross-sectional view of an embodiment in which weld-adhesion between a reinforcing ring and a protecting cover is performed on a radial outer circumferential side of the magnetic encoder, in an example in which the magnetic encoder of the present invention is adopted in a combination seal structure.

### DESCRIPTION OF THE PREFERRED EMBODIMENTS

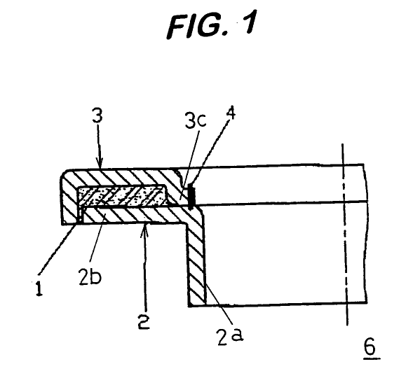

FIG. 1 is a partial cross-sectional view of an example in which weld-adhesion between a reinforcing ring 2 and a protecting cover 3 is performed on a radial inner circumferential side of a magnetic encoder 6.

The magnetic encoder 6 is mounted on a wheel bearing in order to detect a rotation number. The magnetic encoder 6 forms a pulse train by means of a magnetic force, and generates a code.

A sensor (not shown) is disposed opposite to this magnetic encoder 6 (disposed opposite to a magnetic ring 1, in an upper side, in FIG. 1), and a rotation number is detected.

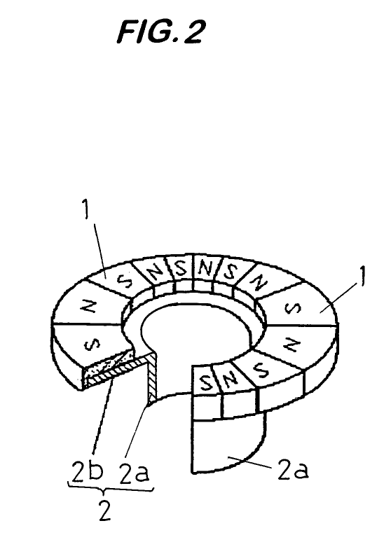

As shown in FIG. 1, the magnetic encoder 6 is comprised of a magnetic ring 1, a reinforcing ring 2, and a protecting cover 3. The magnetic ring 1 is fixed to a reinforcing ring 2, and which is circumferentially magnetized with alternate S poles and N poles as shown in FIG. 2. The protecting cover 3 is made of a non-magnetic material and wraps around the magnetic ring 1 as shown in FIG. 1.

In an embodiment shown in FIG. 1, the reinforcing ring 2 is composed of a cylindrical part 2a extending in an axial direction and a flange part 2b extending outwardly in a radial direction from an end part of this cylindrical part 2a. The magnetic ring 1 is fixed to the flange part 2b of this reinforcing ring 2 on the outer surface of flange part 2b in an axial direction.

In an embodiment shown in FIG. 1, a cylindrical part 2a is mounted on an outer circumference of a rotating member (e.g. axis) (not shown).

First, a reinforcing ring 2 is formed using a cold rolled steel plate (SPCC).

On the other hand, single magnet of ferrite are formed as ring-like shape, and the said formed ring-like shape single magnet of ferrite is circumferentially magnetized with alternate S poles and N poles. Thereby, a magnetic ring 1 as a multi-pole magnet was prepared.

As shown in FIG. 2, a magnetic ring 1 is adhered to a flange part 2b of a reinforcing ring 2 using an epoxy series adhesive.

Then, a ring-like shaped protecting cover 3 made into a form wrapping around a magnetic ring 1 is prepared using aluminium.

A radial inner circumferential side end part of a protecting cover 3 is bent toward a radial inner circumferential side as expressed by a symbol 3c in FIG. 1. And, a protecting cover 3 is attached to a reinforcing ring 2 so that the protecting cover 3 covers a magnetic ring 1.

Then, using YAG laser, an end part of the protecting cover 3 is directly fixed to a reinforcing ring 2 by welding, at a position of a symbol 4 in FIG. 1. Although it is not shown, weld-adhesion was performed at six places circumferentially at a predetermined interval. Thereby, the magnetic encoder 6 of the present invention is manufactured.

As a result of various performance tests, it was demonstrated that the thus constructed magnetic encoder 6 has a tough integrated structure, and is excellent in the performance of protecting a magnetic ring 1.

In addition, since manufacturing is easy, the productivity is improved and, accompanied therewith, there can be provided a magnetic encoder which is also advantageous in the cost.

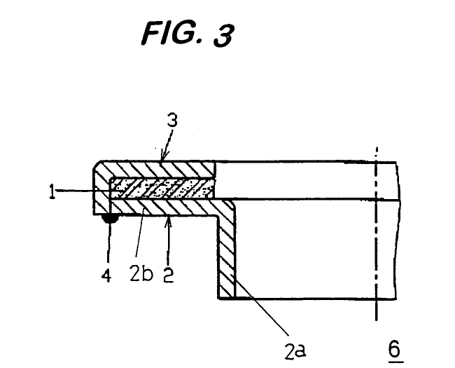

In an embodiment shown in FIG. 3, weld-adhesion to a reinforcing ring 2 is performed at a radial outer circumferential side end part of a protecting cover 3. In FIG. 3, although it is not show, weld-adhesion is performed at a position of a symbol 4, and is performed at five places circumferentially at a predetermined interval.

Since weld-adhesion is not performed on a radical inner circumferential side, a bent part 3c is not provided at an inner circumferential side end part of a protecting cover 3, unlike the embodiment shown in FIG. 1.

Since others are the same as those of the embodiment shown in FIG. 1, explanations thereof will be omitted.

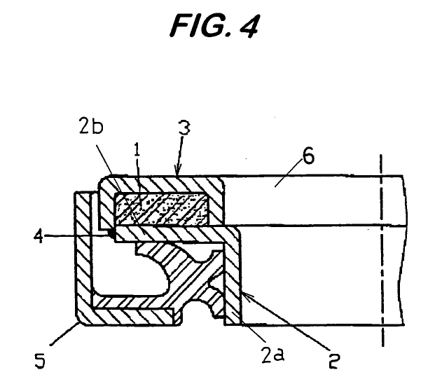

In the embodiment shown in FIGS. 1 and 3, a magnetic encoder 6 was used alone. In an embodiment shown in FIG. 4, a magnetic encoder 6 is used in a part of combination seal structure. The magnetic encoder 6 is combined with other sealing member 5. The magnetic encoder 6 and the sealing member 5 rotate relatively. The magnetic encoder 6 is used as an interrupting and sliding material for a part of a sealing material.

In an embodiment shown in FIG. 4, a protecting cover 3 is weld-adhered to a reinforcing ring 2 at a radial outer circumferential side end part, as in the embodiment shown in FIG. 3.

In FIG. 4, although it is not shown, weld-adhesion is performed at a position of a symbol 4, and is performed at four places circumferentially at a predetermined interval.

Unlike the embodiment shown in FIG. 3, a radial inner circumferential side end of a protecting cover 3 is bent toward an axial inner directional. Whereby, a radial inner circumferential side end of a magnetic ring 1 is covered with a protecting cover 3. So that, according to the embodiment shown in FIG. 4, the performance of protecting a magnetic ring 1 is excellent than that of the embodiment shown in FIG. 3.

Since others are the same as those of the embodiment shown in FIG. 1, explanations thereof will be omitted.

In the aforementioned examples, a magnetic ring 1 is formed using a single magnet of ferrite, but a rare earth magnet may be used as a single magnet. As the rare earth magnet, alloys combining a rare earth element such as neodymium and samarium, and cobalt, iron or the like can be used. For example, a neodymium-iron-boron alloy, and a samarium-iron-nitrogen alloy can be used.

In addition, in the above description, upon adhesion of amagnetic ring 1 to a reinforcing ring 2, an epoxy series adhesive is used, but various adhesives such as cyan series, phenol series, rubber series and urethane series can be used.

Alternatively, a magnetic ring 1 may be adhesion-fixed to a reinforcing ring 2 without using an adhesive. For example, a magnetic powder of ferrite, or a magnetic powder of a rare earth is mixed into a rubber material (e.g. nitrile rubber, hydrogenated nitrile rubber, acryl rubber, butyl rubber, fluorine rubber etc.) or a plastic material, and directly vulcanization-molded with a reinforcing ring 2, whereby, adhesion fixing can be performed. In this case, after adhesion fixing is performed by vulcanization molding, it is magnetized circumferentially with alternate S poles and N poles to form a magnetic ring, and then, a protecting cover 3 is attached. As the aforementioned magnetic powder of a rare earth, a combination of neodymium (Nd), iron (Fe) and boron (B), a combination of samarium (Sm), iron (Fe) and nitrogen (N) can be used.

However, as explained in the above example, when a magnetic ring 1 is formed using a single magnet, since magnetizing process magnetizing circumferentially with alternate S poles and N poles to form a magnetic ring can be conducted in advance and, thereafter, adhesion-fixing may be performed to a reinforcing ring 2 using an adhesive, it is advantageous in the attachment workability.

In the above example, a reinforcing ring 2 is formed of a cold rolled steel (SPCC), but a plate composed of a magnetic material such as SUS 430 and the like can be used. In any event, when a magnetic material is used as a reinforcing ring 2, since the magnetic field can be widened, and a magnetic force from a magnetic encoder 6 can be increased, it is advantageous.

In the above example, aluminium was adopted as a non-magnetic material for forming a protecting cover 3, but a plastic and a non-magnetic austenitic stainless, for example, SUS304 and SUS301 can be used.

In the above example, welding between a protecting cover 3 and a reinforcing ring 2 is performed at 4 to 6 places in a circumferential direction, but since it is enough as far as firm integration is realized, welding may be performed at plural places, for example, at 3 to 6 places.

In addition, taking distortion and thermal influence on the other parts than a welding parts into consideration, welding is conducted by YAG laser welding, but as far as distortion and thermal influence on the other parts than welding parts can be minimized, the conventionally known welding methods such as micro-spot welding using other laser light can be used.

In the above example, a rotating member (e.g. rotating axis) (not shown) is present on a radial inner side of a reinforcing ring 2, and a reinforcing ring 2 is attached to its outer circumference. It is natural that the magnetic encoder 6 of the present invention can be also used when a rotating member is present on a radial outer side of a reinforcing ring 2, and a reinforcing ring 2 is attached to an inner circumference of the rotating member.

In the foregoing, preferable embodiments of the present invention have been explained by referring to attached drawings, but the present invention is not limited by such embodiments, and can be changed into various forms in the technical scope which is grasped from the description of claims.

What is claimed is:

1. A magnetic encoder which is used in a wheel bearing, that forms a pulse train by means of amagnetic force, and generates a code, comprising:
a magnetic ring, a reinforcing ring, and a protecting cover, characterized that:
said magnetic ring is fixed to said reinforcing ring and circumferentially magnetized with alternate S poles and N poles,
said protecting cover is made of a non-magnetic material and wraps around said magnetic ring, and
a plural number of weld-adhering parts are provided between an end part and/or end parts on a radial inner circumferential side and/or a radial outer circumferential side of said protecting cover, and said reinforcing ring.

2. A magnetic encoder according to claim 1, wherein the weld-adhering part is formed by weld-adhering an end part and/or end parts on a radial inner circumferential side and/or a radial outer circumferential side of the protecting cover to the reinforcing ring by micro-spot welding using the laser light.

3. A magnetic encoder according to claim 1, wherein the weld-adhering part is formed by weld-adhering an end part and/or end parts on a radial inner circumferential side and/or a radial outer circumferential side of the protecting cover to the reinforcing ring with YAG laser.
